(19) United States
(12) Patent Application Publication
(10) Pub. No.: US 2012/0244700 A1
(43) Pub. Date: Sep. 27, 2012

(54) METHODS FOR FABRICATING SEMICONDUCTOR DEVICES INCLUDING METAL SILICIDE

(75) Inventors: Ralf RR RICHTER, Dresden (DE); Ronny RP PFUTZNER, Dresden (DE)

(73) Assignee: GLOBALFOUNDRIES INC., Grand Cayman (KY)

(21) Appl. No.: 13/069,062

(22) Filed: Mar. 22, 2011

(51) Int. Cl. H01L 21/28

(52) U.S. Cl. 438/664; 438/683; 257/E21.158

(57) ABSTRACT

Embodiments of methods for fabricating the semiconductor devices are provided. The method includes forming a metal silicide in an upper portion of a gate electrode structure and in an active semiconductor region laterally adjacent to the gate electrode structure. A first portion of the metal silicide formed in the upper portion of the gate electrode structure is removed.

### FIELD OF THE INVENTION

The present invention relates generally to methods for fabricating semiconductor devices, and more particularly relates to methods for fabricating semiconductor devices by forming a metal silicide in an upper portion of a gate electrode structure and removing a portion of the metal silicide.

### BACKGROUND OF THE INVENTION

The majority of present day integrated circuits (ICs) are implemented by using a plurality of interconnected field effect transistors (FETs) or MOS transistors in the form of CMOS, NMOS, and PMOS elements that are formed on a chip area. A FET includes a gate electrode structure as a control electrode and spaced apart active areas, e.g., source and drain electrodes, between which a current can flow. A control voltage applied to the gate electrode structure controls the flow of current through a channel region between the source and drain electrodes.

Typically, feature sizes of these circuit elements are steadily decreasing with the introduction of newer circuit technologies to provide currently available integrated circuits having a critical dimension of 40 nm and less at the device level, thereby achieving an improved degree of performance in terms of speed and/or functionality. A reduction in the size of transistors is an important aspect in steadily improving device performance of complex integrated circuits, such as CPUs. The reduction in size often brings about an increased switching speed and enhanced signal performance. However, the shrinkage on the overall dimensions of the individual transistor elements results in increased packing density and reduced distance between neighboring circuit elements including a reduction in the lateral distance between gate electrode structures and contacts that form interconnections between individual circuit elements and/or wiring. As the distance for positioning contacts between gate electrode structures decreases, it is more difficult to consistently provide a sufficient margin between the gate electrode structures and adjacent contacts for ensuring that none of the contacts touch any of the gate electrode structures that may otherwise cause shorting and/or current leakage.

This challenge is further exasperated in that the upper portions of gate electrode structures often have metal silicide formed therein that increases the size of the upper portions and further reduces the clearance with an adjacent contact. For example, FIG. 1 illustrates a semiconductor device 10 where two closely spaced transistors 12 and 14 are provided. The transistors 12 and 14 include corresponding gate electrode structures 16 and 18 that are formed on a silicon-on-insulator 20. Interposed between the two transistors 12 and 14 is a contact 15. Metal silicide is formed at the upper portions 22 and 24 of the gate electrode structures 16 and 18. The metal silicide is slightly enlarged particularly in the lateral direction relative the lower portions of the gate structures 16 and 18 between the sidewall spacers 26, giving the transistors 12 and 14 a slight “mushroom-shape.” Typically, the upper portions 22 and 24 of the gate electrode structures 16 and 18 are slightly enlarged as a result of the metal silicide forming process where metal atoms replace smaller silicon atoms in the upper portions 22 and 24, thereby causing an increase in volume. Unfortunately, the increase in volume of the upper portions 22 and 24 of the gate electrode structures 16 and 18 reduces the clearance with the contact 15, increasing the possibility of the contact 15 shorting to one of the gate electrode structures 16 or 18.

Accordingly, it is desirable to provide methods for fabricating semiconductor devices with improved margins or clearance between the gate electrode structures and adjacent contacts. Furthermore, other desirable features and characteristics of the present invention will become apparent from the subsequent detailed description and the appended claims, taken in conjunction with the accompanying drawings and the foregoing technical field and background.

### SUMMARY OF THE INVENTION

Methods for fabricating semiconductor devices are provided herein. In accordance with an exemplary embodiment, a method for fabricating a semiconductor device includes forming a metal silicide in an upper portion of a gate electrode structure and in an active semiconductor region laterally adjacent to the gate electrode structure. A first portion of the metal silicide formed in the upper portion of the gate electrode structure is removed.

In accordance with another exemplary embodiment, a method for fabricating a semiconductor device is provided. The method includes depositing metal on an upper portion of a gate electrode structure and on an active semiconductor region that is laterally adjacent to the gate electrode structure. A heat treatment is performed to initiate a chemical reaction between a first portion of the metal and silicon that is contained in the upper portion of the gate electrode structure and in the active semiconductor region to form a metal silicide. An unreacted portion of the metal is removed with a first cleaning or etching process that selectively removes the metal without removing the metal silicide. A first portion of the metal silicide formed in the upper portion of the gate electrode structure is removed with a second cleaning or etching process.

### BRIEF DESCRIPTION OF THE DRAWINGS

Embodiments of the present invention will hereinafter be described in conjunction with the following drawing figures, wherein like numerals denote like elements, and wherein:

FIG. 1 schematically illustrates, in cross-sectional view, a prior art semiconductor device; and

FIGS. 2-6 schematically illustrate, in cross-sectional views, a semiconductor device during stages of its fabrication in accordance with exemplary embodiments.

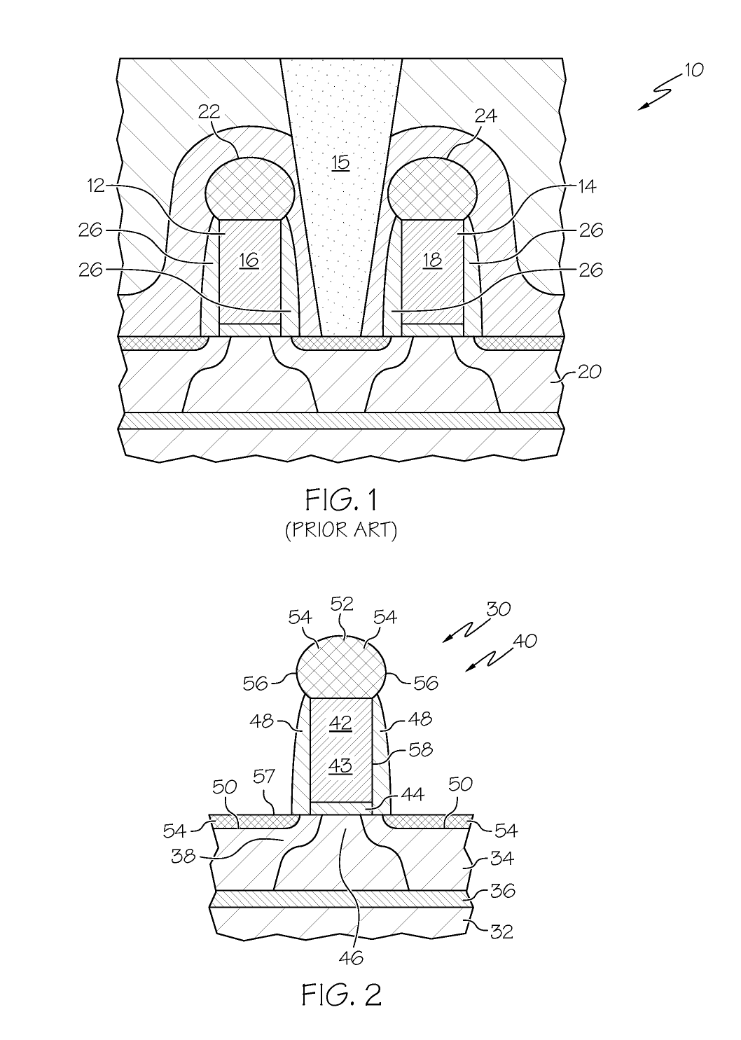

### DETAILED DESCRIPTION

The following Detailed Description is merely exemplary in nature and is not intended to limit the invention or the application and uses of the invention. Furthermore, there is no intention to be bound by any theory presented in the preceding Background of the Invention or the following Detailed Description.

Various embodiments contemplated herein relate to methods for fabricating semiconductor devices. During intermediate stages of the fabrication of a semiconductor device, a metal silicide is formed in an upper portion of the gate electrode structure and in an active semiconductor region that is laterally adjacent to the gate electrode structure. A portion of the metal silicide is removed from the upper portion of the gate electrode structure. A wet etching process or a dry etching process is used to remove an outer lateral portion of the metal silicide formed in the upper portion of the gate electrode structure. By removing the portion of the metal silicide, the lateral or transverse dimensions of the upper portion of the gate electrode structure are reduced. During a subsequent intermediate stage in the fabrication of the semiconductor device, a contact may be formed adjacent to the gate electrode structure. Because the lateral dimensions of the upper portion of the gate electrode structure have been reduced by removing a portion of the metal silicide, the clearance between the upper portion of the gate electrode structure and the adjacent contact is increased, reducing the possibility of the contact shorting with the gate electrode structure.

FIGS. 2-6 illustrates schematically, in cross-sectional view, a semiconductor device 30 and process steps for fabricating the device 30 in intermediate fabrication stages. As illustrated in FIG. 2, the semiconductor device 30 includes a substrate 32. Above the substrate 32 is a semiconductor layer 34, which may represent a silicon-containing semiconductor material that includes a high fraction of silicon in a crystalline state. As shown, a buried insulating layer 36 is positioned between the substrate 32 and the semiconductor layer 34, and the combination of layers 32, 34 and 36 represents a silicon-on-insulator (SOI). In other cases, the semiconductor layer 34 may be formed on a crystalline semiconductor material of the substrate 32, thereby providing a “bulk” configuration. It should be appreciated that an SOI configuration and a bulk configuration may be used concurrently in the device 30 in different device areas if considered advantageous.

In an exemplary embodiment, the semiconductor device 30 includes an active region 38, which is to be understood as a semiconductor region formed in the semiconductor layer 34 and/or having received an appropriate dopant profile as required for forming a transistor element. As illustrated, the active region 38 corresponds to the transistor 40, which may represent an N-channel transistor or a P-channel transistor.

The transistor 40 includes a corresponding gate electrode structures 42. The gate electrode structure includes electrode material 43, such as silicon, silicon-germanium, metal-containing materials and the like. The gate electrode structure 40 also includes a gate insulation layer 44 that separates the electrode material 43 from the channel region 46 of the transistor 40. The channel region 46 is formed in the active region 38 underlying the gate electrode structure 42.

As illustrated in accordance with one embodiment, the semiconductor device 30 includes sidewall spacers 48 formed over a portion of the active region 38 and the gate electrode structure 42. The sidewall spacers 48 may be formed of a spacer material or materials, such as, for example, silicon oxide, silicon nitride, and the like, or combinations thereof. The sidewall spacers 48 can be used as an implantation mask during various fabrication stages of an implantation sequences, in order to establish the desired vertical and lateral dopant profiles for the drain and source regions 50 on the basis of well-established techniques.

Formed at the upper portion 52 of the gate electrode structure 42 and the upper portions of the source and drain regions 50 is metal silicide 54. The metal silicide 54 may be formed from a refractory metal, such as, for example, cobalt, nickel, titanium, tantalum, platinum, palladium, rhodium, and mixtures thereof that have been chemically reacted with silicon in the corresponding portions of the semiconductor device 30 to form the metal silicide 54.

The semiconductor device 30 as described in the foregoing paragraphs may be formed on the basis of the following processes. After establishing the active region 38, for instance, by ion implantation, the gate electrode structure 42 may be formed by forming an appropriate layer stack and patterning the same using lithography and etch techniques.

The sidewall spacers 48 are formed by depositing a spacer forming material over the active region 38 and the gate electrode structure 42, and a substantially anisotropic etch process. Thereafter, a layer of silicide forming metal is deposited and subsequently one or more heat treatments may be performed to initiate a chemical reaction to form the metal silicide 54. A cleaning or etching process that selectively does not remove the metal silicide 54 may be used to remove any unreacted metal.

As illustrated, the formation of the metal silicide causes the upper portion 52 of the gate electrode structure 42 to be slightly enlarged relative to the remaining lower portion of the gate electrode structure 42 between the sidewall spacers 48. In particular, the outer lateral portion 56 of the upper portion 52 extends horizontally beyond the vertical walls 58 of the lower portion of the gate electrode structure 42.

In an exemplary embodiment as illustrated in FIG. 3, the metal silicide 54 is exposed to an etching process 60 that removes a portion of the metal silicide 54 from the semiconductor device 30. The etching process 60 is effective for removing metal silicide. As illustrated, the etching process 60 removes a portion of the metal silicide 54 including the outer lateral portion 56 of the upper portion 52 of the gate electrode structure 42, and the outer upper portion 57 (see FIG. 2) of the metal silicide 54 formed in the active region 38. The remaining portion 62 of the upper portion 52 of the gate electrode structure 42 has a reduced cross-section relative to the cross-section of the upper portion 52 as illustrated in FIG. 2. In particular, the reduced cross-section of the remaining portion 62 is narrower, importantly, in the transverse direction, and as such, allows for greater clearance between a subsequently formed adjacent contact.

The etching process 60 may be a wet etching process or a dry etching process. In one example, the etching process 60 is a wet etching process that removes a portion of the metal silicide 54 with a sulfuric acid/hydrogen peroxide mixture (e.g. SPM etching process) and/or an ammonium hydrogen peroxide mixture (e.g. APM etching process). In another example, the etching process 60 is a dry etching process using a plasma assisted etching process that removes a portion of the metal silicide 54.

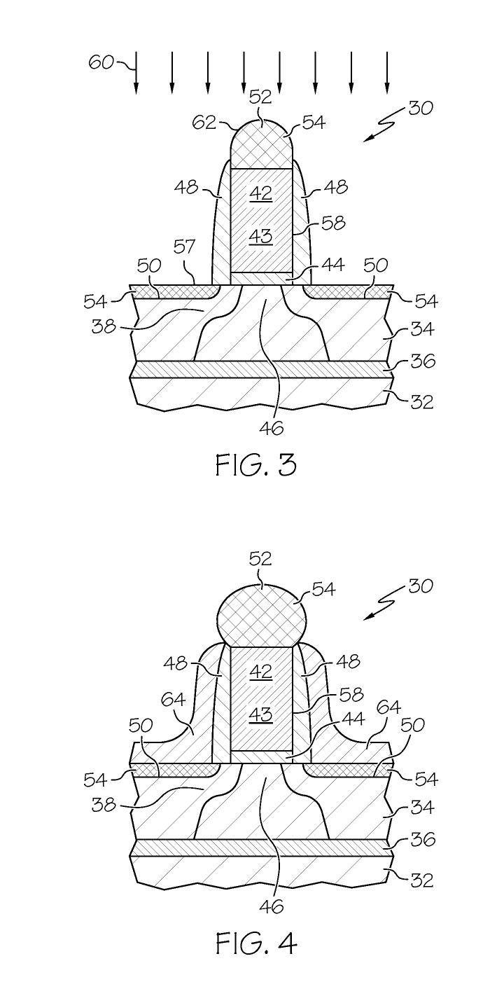

In an alternative exemplary embodiment, the metal silicide 54 is selectively removed from the upper portion 52 of the gate electrode structure and not from the active region 38 laterally adjacent to the gate electrode structure 42. In particular and with reference to FIG. 4, the semiconductor device 30 is selectively covered with a protective layer 64. The protective layer 64 may be formed of photoresist, silicon nitride, and the like. As illustrated, the protective layer 64 covers the sidewall spacers 48 and the metal silicide 54 formed in the active region 38 while leaving the metal silicide 54 formed in the upper portion 52 of the gate electrode structure 42 exposed. The protective layer 64 may be formed by depositing a layer of masking material and patterning the layer on the basis of well-known techniques.

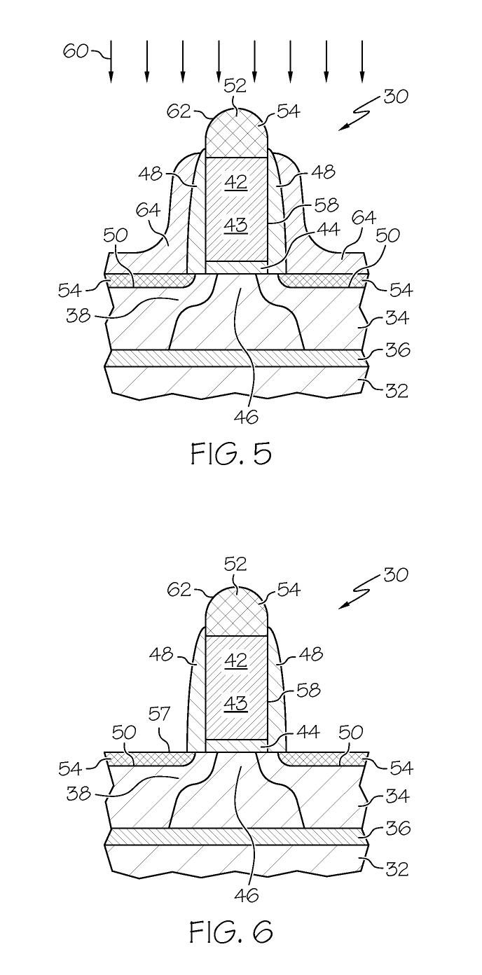

Referring to FIG. 5, the semiconductor device 30 is then subjected to the etching process 60 that removes a portion of the metal silicide 54 formed in the upper portion 52 of the gate electrode structure 42 while the metal silicide 54 formed in the active region 38 is protected by the protective layer 64. The inventors have found that in some cases, the metal silicide 54 formed in the upper portion 52 of the gate electrode structure 42 is more robust than the metal silicide 54 formed in the active region 38, which may otherwise become fragile if reduced in thickness by the etching process 60. Accordingly, by protecting the metal silicide 54 formed in the active region 38 with the protective layer 64, the inventors have discovered that the etching process 60 may be more aggressive. The etching process 60 is preferably an aggressive wet etching process (e.g. using a relatively high concentration of etchant) or an aggressive dry etching process, and most preferably an aggressive dry etching process, such as, for example, plasma assisted etching. As illustrated, the etching process 60 removes a portion of the metal silicide 54 including the outer lateral portion 56 of the upper portion 52 of the gate electrode structure 42, allowing for greater clearance between gate electrode structure 42 and a subsequently formed adjacent contact.

In an exemplary embodiment, the protective layer 64 remains on the semiconductor device 30 through subsequent processing including the formation of contacts. For example, if the protective layer 64 is silicon nitride, it is preferred that at least a portion of the protective layer 64 remains on the semiconductor device 30.

Alternatively and as illustrated in FIG. 6, the protective layer 64 may be removed on the basis of well-known techniques. For example, if the protective layer 64 is photoresist, it is preferred that the protective layer 64 is removed from the semiconductor device 30 before the next fabrication step.

Accordingly, methods for fabricating semiconductor devices have been described. The various embodiments include during intermediate stages of the fabrication of a semiconductor device, forming a metal silicide in an upper portion of the gate electrode structure and in an active semiconductor region that is laterally adjacent to the gate electrode structure. A portion of the metal silicide is removed from the upper portion of the gate electrode structure. Preferably, a wet etching process or a dry etching process is used to remove an outer lateral portion of the metal silicide formed in the upper portion of the gate electrode structure. By removing the portion of the metal silicide, the lateral or transverse dimensions of the upper portion of the gate electrode structure are reduced. During a subsequent intermediate stage in the fabrication of the semiconductor device, a contact may be formed adjacent to the gate electrode structure. Because the lateral dimensions of the upper portion of the gate electrode structure have been reduced by removing a portion of the metal silicide, the clearance between the upper portion of the gate electrode structure and the adjacent contact is increased, reducing the possibility of the contact shorting with the gate electrode structure.

While at least one exemplary embodiment has been presented in the foregoing Detailed Description, it should be appreciated that a vast number of variations exist. It should also be appreciated that the exemplary embodiments are only examples, and are not intended to limit the scope, applicability, or configuration of the invention in any way. Rather, the foregoing Detailed Description will provide those skilled in the art with a convenient road map for implementing an exemplary embodiment of the invention, it being understood that various changes may be made in the function and arrangement of elements described in an exemplary embodiment without departing from the scope of the invention as set forth in the appended Claims and their legal equivalents.

1. A method for fabricating a semiconductor device, the method comprising:
forming a metal silicide in an upper portion of a gate electrode structure and in an active semiconductor region laterally adjacent to the gate electrode structure, wherein forming the metal silicide in the upper portion defines a metal silicide upper portion having a maximum lateral dimension; and
removing a first portion of the metal silicide formed in the upper portion of the gate electrode structure, wherein removing the first portion includes removing an outer lateral portion of the metal silicide formed in the upper portion of the gate electrode structure to reduce the maximum lateral dimension of the metal silicide upper portion.

2. The method according to claim 1, further comprising removing a second portion of the metal silicide formed in the active semiconductor region.

3. The method according to claim 1, wherein removing the first portion includes using a wet etching process or a dry etching process to remove the first portion of the metal silicide.

4. The method according to claim 1, wherein removing the first portion includes using an etchant comprising sulfuric acid, hydrochloric acid, hydrogen peroxide, or mixtures thereof to etch the first portion.

5. (canceled)

6. The method according to claim 1, wherein removing the first portion includes selectively removing the first portion of the metal silicide without removing a second portion of the metal silicide formed in the active semiconductor region.

7. The method according to claim 1, further comprising forming a protective layer over the metal silicide formed in the active semiconductor region after forming a metal silicide and before removing the first portion of the metal silicide.

8. The method according to claim 7, wherein forming the protective layer includes depositing a layer of protective material and patterning the layer of protective material to form the protective layer.

9. The method according to claim 7, wherein forming the protective layer includes forming a layer of photoresist or silicon nitride.

10. The method according to claim 7, further comprising removing the protective layer after removing the first portion of the metal silicide.

11. The method according to claim 7, wherein removing the first portion includes using a plasma etching process to remove the first portion of the metal silicide.

12. The method according to claim 1, wherein forming the metal silicide includes depositing metal on the active semiconductor region and the upper portion of the gate electrode structure and performing a heat treatment to initiate a chemical reaction of the metal and silicon that is contained in the active semiconductor region and the upper portion of the gate electrode structure.

13. The method according to claim 12, wherein performing the heat treatment includes chemically reacting a first portion of the metal with silicon to form the metal silicide such that a second portion of the metal is unreacted, and the method further comprises removing the second portion of metal with a cleaning or etching process that does not remove the metal silicide.

14. The method according to claim 12, wherein forming the metal silicide includes depositing the metal selected from the group consisting of nickel, cobalt, titanium, tantalum, platinum, palladium, rhodium, and mixtures thereof.

15. A method for fabricating a semiconductor device, the method comprising:
depositing metal on an upper portion of a gate electrode structure and on an active semiconductor region that is laterally adjacent to the gate electrode structure;
performing a heat treatment to initiate a chemical reaction between a first portion of the metal and silicon that is contained in the upper portion of the gate electrode structure and in the active semiconductor region to form a metal silicide, wherein forming the metal silicide in the upper portion defines a metal silicide upper portion having a maximum lateral dimension;
removing an unreacted portion of the metal with a first cleaning or etching process that selectively removes the metal without removing the metal silicide; and
removing a first portion of the metal silicide formed in the upper portion of the gate electrode structure with a second cleaning or etching process, wherein removing the first portion includes removing an outer lateral portion of the metal silicide formed in the upper portion of the gate electrode structure to reduce the maximum lateral dimension of the metal silicide upper portion.

16. The method according to claim 15, further comprising forming a protective layer over the metal silicide formed in the active semiconductor region after removing the unreacted portion of the metal and before removing the first portion of the metal silicide.

17. The method according to claim 16, wherein forming the protective layer includes depositing a layer of protective material and patterning the layer of protective material to form the protective layer.

18. The method according to claim 16, wherein forming the protective layer includes forming a layer of photoresist or silicon nitride.

19. The method according to claim 16, further comprising removing the protective layer after removing the first portion of the metal silicide.

20. The method according to claim 16, wherein removing the first portion includes using a plasma etching process to remove the first portion of the metal silicide.
